(19) United States
(12) Patent Application Publication
(10) Pub. No.: US 2011/0207035 A1
(43) Pub. Date: Aug. 25, 2011

(54) Exposure apparatus and exposure method

(75) Inventors: Akiya Saito, Kanagawa (JP); Akitoshi Suzuki, Shizuoka (JP); Toru Aida, Kanagawa (JP); Shinobu Hayashi, Shizuoka (JP)

(73) Assignees: Sony Corporation, Tokyo (JP); Sony DADC Corporation, Tokyo (JP)

(21) Appl. No.: 12/932,033

(22) Filed: Feb. 16, 2011

(30) Foreign Application Priority Data
Feb. 23, 2010 (JP) P2010-037496

(51) Int. Cl. G03F 7/20; G03B 27/52

(52) U.S. Cl. 430/30; 355/55

(57) ABSTRACT

An exposure apparatus includes an exposure unit selectively performing exposure on a resist layer with a first laser beam, focused by a lens system, in a pattern including pits and lands arranged in a scanning direction; a detecting unit detecting a reflection of a second laser beam applied through the lens system to the resist layer selectively exposed to the first laser beam, the second laser beam being produced by changing a focal length of the lens system such that the resist layer is prevented from responding thereto; a calculating unit calculating, from a result of the detection, a displacement between center axes of signal waveforms representing beams reflected from first and second portions of the pattern having a smallest width and a larger width, respectively; a setting unit setting the focal length of the lens system to such a value that the displacement is maximal; and a control unit controlling the exposure unit to expose the resist layer to the first laser beam focused with the focal length set by the setting unit.

### BACKGROUND OF THE INVENTION

1.Field of the Invention

The present invention relates to an exposure apparatus and an exposure method in which a laser beam is applied to a resist layer provided on a substrate to be subjected to microfabrication in which the resist layer having areas thereof exposed to the laser beam is developed.

2.Description of the Related Art

The recording density of recent optical discs has been increasing, and high-density optical discs such as Blu-ray Disc (a registered trademark) have been gradually spreading.

While digital versatile discs (DVDs) that have already been widespread have a storage capacity of 4.7 gigabytes (GB) per disc (per recording layer), Blu-ray Disc has a significantly larger storage capacity of 25 GB.

Such a densification is realized by reducing the size of the pit pattern, including pits and lands, of a master optical disc manufactured in a mastering process. The pit pattern is to be transferred to an optical-disc-manufacturing stamper.

To increase the density, in an exemplary mastering process for Blue-ray Disc, the pit pattern of a master disc is formed into a predetermined shape by selectively exposing a resist layer containing a defective transition-metal oxide to light and developing the resist layer, as disclosed in Japanese Unexamined Patent Application Publication No. 2003-315988.

### SUMMARY OF THE INVENTION

In a microfabrication method disclosed in Japanese Unexamined Patent Application Publication No. 2003-315988, when the focal length of a laser beam to which a resist layer is to be selectively exposed is adjusted, the focus offset is gradually changed so as to eliminate bands of the laser beam, and a point corresponding to a specific band where the outline of the laser beam appears most distinct is determined to be the optimum point. In addition, a plurality of test cuts are made in a disc by performing exposure while gradually changing the focus offset and by developing the disc. Subsequently, the disc is played by an optical pickup system, and a point where the radio-frequency (RF) waveform has the maximum amplitude is determined as the optimum point.

However, the above method is based on visual examination and is therefore vague. Consequently, the optimum point may not be found correctly, unless the examiner has accumulated experience. In the case where the optimum point is to be set by making test cuts in a disc, it takes some time to prepare the disc with the test cuts. Moreover, even after the adjustment, the disc with the test cuts mounted on a master manufacturing apparatus is to be exchanged with a master disc on which a desired microfabrication is to be actually performed. Such adjustment work is inefficient.

In light of the above, it is desirable to provide an exposure apparatus and an exposure method in which, in an exposure process performed on a resist layer to be subjected to microfabrication performed by developing exposed areas of the resist layer, the focal length of a lens system that focuses a laser beam is adjustable to the optimum value without reducing the efficiency of the overall microfabrication process.

According to an embodiment of the present invention, an exposure apparatus includes the following elements: an exposure unit selectively performing exposure on a resist layer provided on a substrate with a first laser beam focused on the resist layer by a lens system, the resist layer being subjected to microfabrication in which exposed areas thereof exposed to the first laser beam are developed, the exposure being performed in a pattern including pits and lands arranged in a scanning direction; a detecting unit detecting a reflection of a second laser beam applied through the lens system to the resist layer selectively exposed to the first laser beam, the second laser beam being produced by changing a focal length of the lens system such that the resist layer is prevented from responding to the second laser beam; a calculating unit calculating, from a result of the detection by the detecting unit, a displacement between a center axis of a signal waveform representing a beam reflected from a first portion of the pattern having a smallest width and a center axis of a signal waveform representing a beam reflected from a second portion of the pattern having a width larger than that of the first portion; a setting unit setting the focal length of the lens system to such a value that the displacement between the center axes of the signal waveforms that is calculated by the calculating unit for every change in the focal length is maximal; and a control unit controlling the exposure unit to expose the resist layer to the first laser beam focused thereon by the lens system with the focal length that is set by the setting unit.

According to another embodiment of the present invention, an exposure method includes the following steps: detecting a reflection of a second laser beam applied to a resist layer provided on a substrate, the second laser beam being set such that the resist layer is prevented from responding thereto, the resist layer being subjected to microfabrication in which exposure is selectively performed thereon with a first laser beam focused by a lens system of an exposure apparatus and exposed areas thereof are developed, the exposure being performed in a pattern including pits and lands arranged in a scanning direction; calculating, from a result of the detection, a displacement between a center axis of a signal waveform representing a beam reflected from a first portion of the pattern having a smallest width and a center axis of a signal waveform representing a beam reflected from a second portion of the pattern having a width larger than that of the first portion; and controlling the exposure apparatus to perform exposure on the resist layer by setting a focal length of the lens system to such a value that the displacement between the center axes of the signal waveforms that is calculated for every change in the focal length is maximal.

In the above embodiments of the present invention, the focal length of the lens system that focuses the laser beam on the resist layer is adjusted by utilizing a characteristic that the displacement between the center axes of the signal waveform representing the beams reflected from the first and second portions of the pattern changes unidirectionally as the formation of the first portion of the pattern that is of the smallest size becomes poorer with the deviation of the focal length from the optimum value. Thus, in the embodiments of the present invention, the focal length of the lens system is adjusted to the optimum value while reduction in the efficiency of the overall microfabrication process is suppressed.

### BRIEF DESCRIPTION OF THE DRAWINGS

FIGS. 1A to 1C show a method of manufacturing a master optical disc;

FIGS. 2A and 2B show a method of manufacturing an optical-disc-manufacturing stamper;

FIG. 3 shows the configuration of an exposure apparatus according to an embodiment of the present invention;

FIG. 4 shows how an asymmetry value is calculated from signal waveforms;

FIG. 5 shows signal waveforms corresponding to different code lengths detected by a detector;

FIG. 6 shows the configuration of an asymmetry calculating unit;

FIGS. 7A to 7C show how the top and bottom levels of signals having the smallest and largest code lengths are obtained from histograms prepared for the respective code lengths; and

FIG. 8 shows a characteristic curve, with the focus offset value that is set in test exposure represented on the horizontal axis, and the test-exposure asymmetry value represented on the vertical axis.

### DESCRIPTION OF THE PREFERRED EMBODIMENTS

Embodiments of the present invention will now be described in detail with reference to the accompanying drawings. The present invention is not limited to the following embodiments, and various changes can be made to the embodiments without departing from the scope of the present invention.

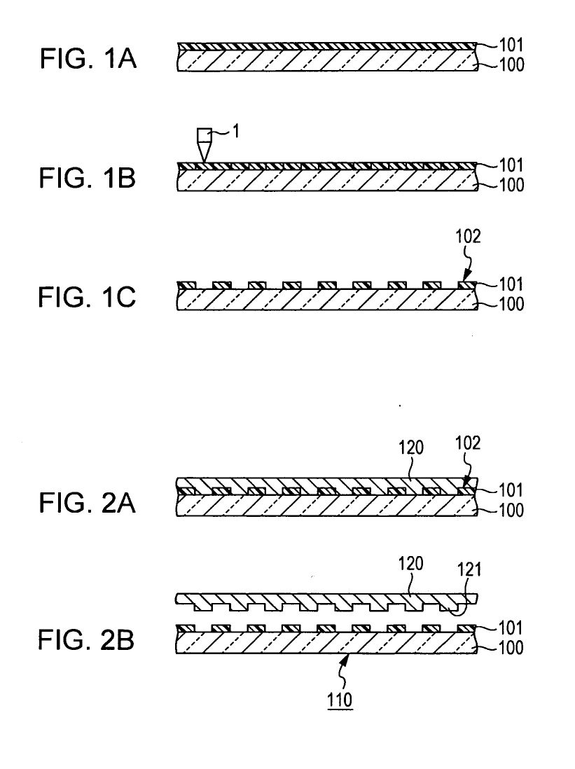

An exposure apparatus according to an embodiment of the present invention performs exposure by applying a laser beam to a resist layer provided on a substrate, the resist layer being subjected to microfabrication in which the exposed areas thereof are developed. Prior to describing a specific configuration of the exposure apparatus according to the embodiment of the present invention, a method of manufacturing a master optical disc, an exemplary microfabrication process performed with the exposure apparatus, will be described with reference to FIGS. 1A to 1C. Hence, the description will proceed in the following order:
1. Method of Manufacturing Master Optical Disc
2. Exposure Apparatus

1. Method of Manufacturing Master Optical Disc

A method of manufacturing a master optical disc includes, as an exemplary microfabrication process performed with the exposure apparatus according to the embodiment of the present invention, a layer forming process, an exposure process, and a development process shown in FIGS. 1A to 1C, respectively.

Layer Forming Process

In the layer forming process, a resist layer 101 containing a defective transition-metal oxide is formed on a substrate 100.

Specifically, as shown in FIG. 1A, the resist layer 101, which is composed of an inorganic resist material, is evenly formed on the substrate 100, which is an insulating member such as a glass or silicon wafer, by sputtering.

As aforementioned, the material for the resist layer 101 is composed of a defective transition-metal oxide, for example, an oxide of metal such as tungsten (W) or molybdenum (Mo). The resist material is to be selected from those having such an oxidation rate that desired photosensitivity, pit shape, and resistance of non-exposed areas to the developing solution are obtained.

Such a defective transition-metal oxide absorbs ultraviolet rays or visible rays and has the chemical properties thereof changed when ultraviolet rays or visible rays are applied thereto. A film made of a resist material composed of a defective transition-metal oxide has a fine grain size. Therefore, the pattern at the boundary between a non-exposed area and an exposed area is distinctly defined. Accordingly, the resolution is increased.

Specific examples of the transition metal employed as the resist material include Ti, V, Cr, Mn, Fe, Nb, Cu, Ni, Co, Mo, Ta, W, Zr, Ru, Ag, and the like. Among the foregoing materials, Mo, W, Cr, Fe, and Nb are preferable. In particular, Mo and W are preferable because their chemical properties change significantly in response to the application of ultraviolet rays or visible rays.

The defective transition-metal oxide may be of a single kind, a combination of two or more kinds, or a combination of a defective transition-metal oxide and any elements other than transition-metal elements.

Exposure Process

In the exposure process, the resist layer 101 formed on the substrate 100 in the layer forming process is selectively exposed to the laser beam in such a manner as to correspond to a pit-and-land pattern representing a signal to be recorded on the optical disc.

Specifically, as shown in FIG. 1B, exposure is selectively performed on the resist layer 101 with an exposure apparatus 1 so that the exposed areas of the resist layer 101 correspond to a signal pattern to be recorded on the optical disc.

The exposure apparatus 1 includes a beam source that emits a laser beam having such a power that the resist layer 101 responds to the laser beam, as described in detail below. The exposure apparatus 1 also includes a lens system including a collimator lens, a beam splitter, and an objective lens. The laser beam is transmitted through the lens system and is thus focused on the resist layer 101. The laser beam employed for exposure has a wavelength suitable for the shape of the pit pattern. For example, a light-emitting diode that emits a beam having a wavelength of 405 nm is employed for Blu-ray Disc (a registered trademark).

Development Process

In the development process, the substrate 100 having the resist layer 101 exposed to the laser beam in the exposure process is developed, whereby a fine pit-and-land pattern is formed in the resist layer 101.

Specifically, as shown in FIG. 1C, the resist layer 101 is developed, whereby a predetermined pit-and-land pattern 102 is formed on the substrate 100.

In the development process, a desired selectivity can be obtained in a wet process performed with, for example, an acid or alkaline solution. The solution to be used is arbitrary, depending on the intended purpose, use, apparatus, facility, and the like. Exemplary alkaline developing solutions used in the wet process include a solution of tetramethylammonium hydroxide, and inorganic alkaline aqueous solutions of KOH, NaOH, Na2Co3, and the like. Exemplary acid developing solutions include solutions of hydrochloric acid, nitric acid, sulfuric acid, phosphoric acid, and the like.

Instead of such a wet process, a dry process called plasma or reactive ion etching (RIE) may be employed for development by adjusting the types of gases and the mixing ratio of the gases.

Thus, a master optical disc 110 is manufactured. In an electroforming process and a mold release process shown in FIGS. 2A and 2B, respectively, the pit-and-land pattern 102 of the master optical disc 110 is transferred to an optical-disc-manufacturing stamper 120, whereby a pit-and-land pattern 121, which is the inverse of the groove-and-land pattern 102, is formed in the stamper 120.

Electroforming Process

In the electroforming process, a stamper is electroformed on the substrate 100 having the pit-and-land pattern 102. Specifically, as shown in FIG. 2A, a metallic nickel film, for example, that is to become the stamper 120 is deposited over the pit-and-land pattern 102 of the master optical disc 110.

Mold Release Process

In the mold release process, the stamper 120 formed in the electroforming process is released from the master optical disc 110. Specifically, as shown in FIG. 2B, the stamper 120 as a metallic nickel film is removed from the master optical disc 110. The stamper 120 obtained in the mold release process has the pit-and-land pattern 121 having a shape that is the inverse of the pit-and-land pattern 102 of the master optical disc 110.

A process of manufacturing an optical disc using the optical-disc-manufacturing stamper 120 is as follows. Polycarbonate, which is a thermoplastic resin, is provided on the stamper 120 having the pit-and-land pattern 121 by injection molding, whereby a resin disc substrate is formed. The resin disc substrate is then released from the stamper 120 and undergoes specific processes. Thus, an optical disc is obtained.

Through the above microfabrication process performed with the exposure apparatus 1, the master optical disc 110 whose pattern is transferred to the optical-disc-manufacturing stamper 120 as the pit-and-land pattern 121 is manufactured.

2.Exposure Apparatus

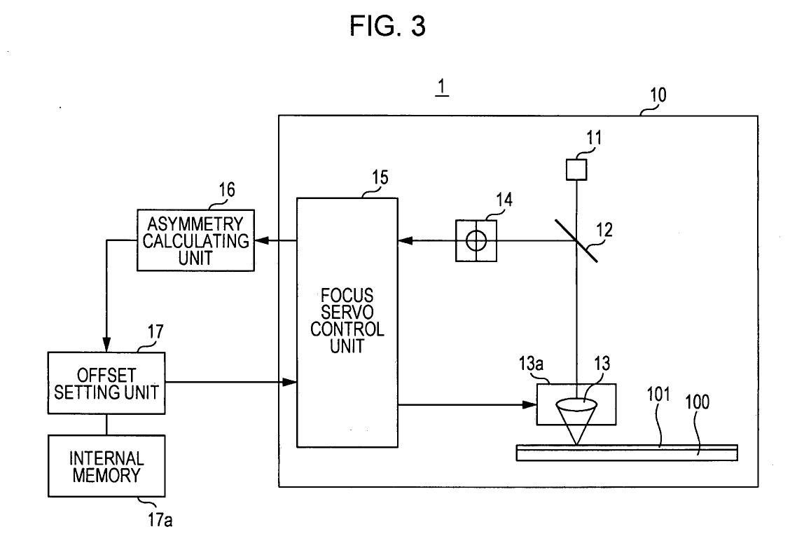

The configuration of the exposure apparatus 1 according to the embodiment of the present invention will now be described with reference to FIG. 3. The exposure apparatus 1 includes an exposure section 10 having a focus servo system and configured to apply a focused laser beam onto the resist layer 101 provided on the substrate 100. The exposure section includes a laser diode 11, a beam splitter 12, a lens system 13, a detector 14, and a focus servo control unit 15.

The laser diode 11 emits a laser beam having a wavelength suitable for resolving a pit-and-land pattern to be microfabricated. For example, the laser diode 11 emits a laser beam having a wavelength of about 405 nm corresponding to a blue-violet semiconductor laser intended for Blu-ray Disc (a registered trademark). The power of the laser diode 11 is adjusted such that a laser beam to which the resist layer 101 responds is emitted.

The beam splitter 12 is provided in the optical path of the beam emitted from the laser diode 11. The beam emitted from the laser diode 11 is transmitted through the beam splitter 12 in the direction of the optical axis of the lens system 13 and is applied to the resist layer 101. The feedback beam from the resist layer 101 is reflected by the beam splitter 12 in such a manner as to be detected by the detector 14.

The beam emitted from the laser diode 11 and transmitted through the beam splitter 12 is focused on the resist layer 101 provided on the substrate 100 by the lens system 13. The lens system 13 includes a lens drive unit 13a with which the focal length to the focal point is adjusted.

The detector 14 is, for example, a four-section detector including four independent photoreceptors. The beam fed back from the resist layer 101 and reflected by the beam splitter 12 is received by the detector 14. The detector 14 opto-electrically converts the received beam into an electrical signal and outputs the electrical signal.

On the basis of the signal from the detector 14 (hereinafter also referred to as the detector signal), the focus servo control unit 15 outputs, to the lens drive unit 13a, a focus drive signal on the basis of which the focal length of the lens system 13 is to be adjusted. Specifically, the focus servo control unit 15 outputs, as the focus drive signal, such a control signal that the focal length represented by a focus offset value that is preset so as to realize the optimum focal length is the same as the actual focal length represented by the detector signal.

In the focus servo system included in the exposure apparatus 1 configured as described above, the lens system 13 is controlled in such a manner as to continuously realize the focal length represented by the focus offset value.

The exposure apparatus 1 configured as described above performs test exposure with different focus offset values so that the focal length of the lens system 13 is adjusted to the optimum value with an appropriate focus offset value that does not reduce the efficiency of the overall microfabrication process. The exposure apparatus 1 includes, in addition to the elements described above, an asymmetry calculating unit 16 and an offset setting unit 17 so that the focus offset value is adjusted by using the resist layer 101 that has undergone test exposure.

The asymmetry calculating unit 16 calculates the asymmetry value on the basis of the detector signal that is output from the detector 14 when a laser beam having such a power that the resist layer 101 shows no response is applied to the resist layer 101 on which test exposure has been performed with different focus offset values.

Test exposure is performed on an area of the resist layer 101 other than the recording area. The recording area is exposed as described above in a pit-and-land pattern corresponding to the signal actually desired to be recorded. The area for test exposure is exposed in a pit-and-land pattern corresponding to a test signal. It is particularly preferable that test exposure be performed on the outside of but near the recording area so that the physical properties of the resist material in the recording area are estimated accurately.

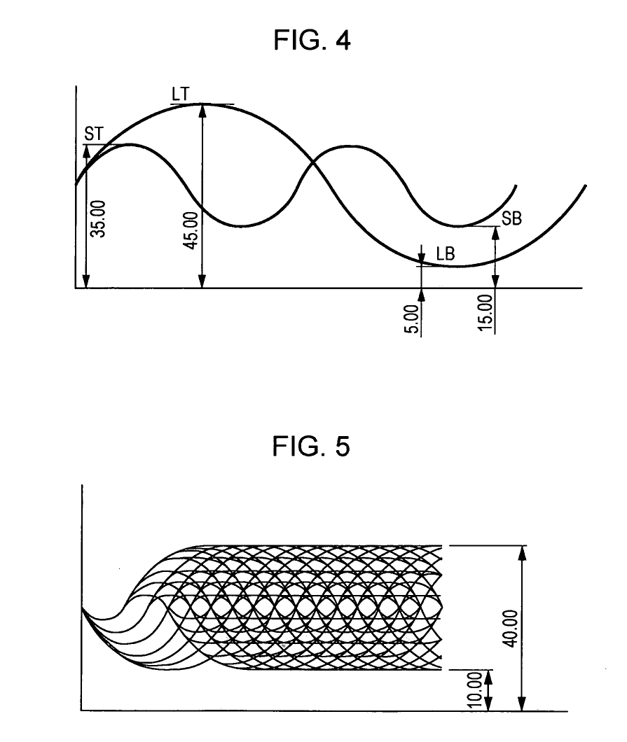

The asymmetry value is the displacement between the center axis of a signal waveform representing a beam reflected from a portion of the pit-and-land pattern where the recorded signal has the smallest code length and the center axis of a signal waveform representing a beam reflected from a portion of the pit-and-land pattern where the recorded signal has the largest code length. Specifically, referring to FIG. 4, the top value LT and bottom value LB of the signal having the largest code length and the top value ST and bottom value SB of the signal having the smallest code length are measured independently, wherefrom the asymmetry value, denoted by Am, is calculated in accordance with the following expression:

Am={(ILT+ILB)−(IST+ISB)}/{2×(ILT−ILB)}

where ILT and ILB denote the top and bottom levels, respectively, of the signal waveform representing the reflected beam corresponding to the largest code length of the recorded signal, and IST and ISB denote the top and bottom levels, respectively, of the signal waveform representing the reflected beam corresponding to the smallest code length of the recorded signal.

In the embodiment, the signal recorded on an optical disc is expressed by the code length defined in units of segments each having a length T, from 2T for the smallest code length to 8T for the largest code length. In addition, as a matter of convenience, the asymmetry value calculated for a laser beam having such a power that the resist layer 101 shows no response is referred to as the “test-exposure asymmetry value”.

The top and bottom levels are measurable from the time response of the reflected beam detected by the detector 14. However, since the waveforms of different code lengths are observed as an eye pattern as shown in FIG. 5, if the signal-to-noise (S/N) ratio is not good, accurate measurements are not obtained.

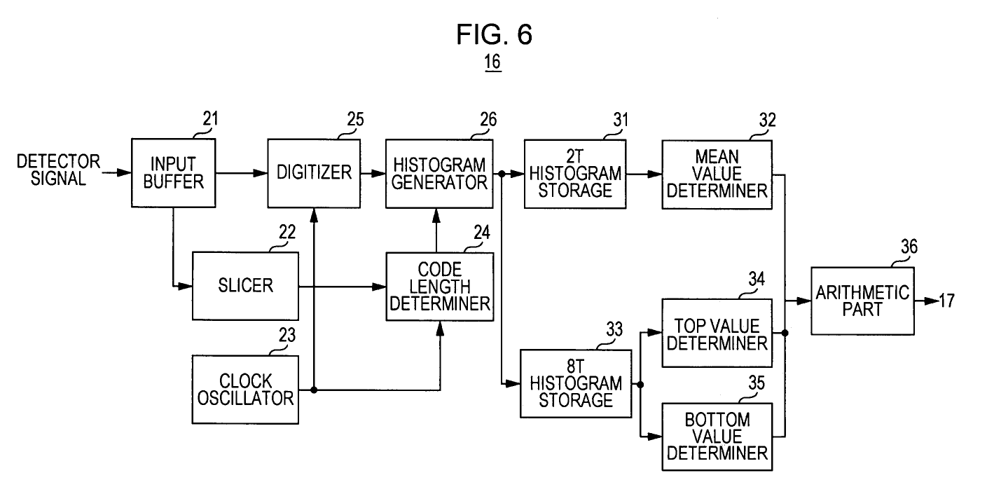

The asymmetry calculating unit 16 includes a signal processing system, shown in FIG. 6, for accurately calculating the test-exposure asymmetry value. Specifically, the asymmetry calculating unit 16 includes an input buffer 21, a slicer 22, a clock oscillator 23, a code length determiner 24, a digitizer 25, a histogram generator 26, a 2T histogram storage 31, an mean value determiner 32, an 8T histogram storage 33, a top value determiner 34, a bottom value determiner 35, and an arithmetic part 36.

The input buffer 21 supplies the slicer 22 and the digitizer 25 with the detector signal generated by opto-electric conversion of the reflected beam detected by the detector 14.

The slicer 22 binarizes the waveform of the signal from the input buffer 21 with respect to a specific slice level, and supplies the binarized signal to the code length determiner 24. The slice level is set to, for example, a value corresponding to the substantial center between the top and bottom levels of the waveform of the signal supplied from the input buffer 21.

The clock oscillator 23, which may or may not be synchronous with the signal from the detector 14, generates a clock signal having a high frequency sufficient for satisfying the sampling theorem used in sampling the information represented by the waveform of the detector signal, and outputs the clock signal to the code length determiner 24 and the digitizer 25.

The code length determiner 24 determines the code length of the signal from the detector 14 for each of time periods on the basis of the pulse width of the binarized signal supplied from the slicer 22 and the number of counts made with reference to the clock signal generated by the clock oscillator 23.

The digitizer 25 samples the signal from the input buffer 21 with reference to the clock signal from the clock oscillator 23, and supplies voltage data obtained by the sampling to the histogram generator 26.

The histogram generator 26 generates histograms of the voltage data, supplied from the digitizer 25, for different code lengths on the basis of the determination made by the code length determiner 24. In each of the histograms, the voltage is represented on the horizontal axis, and the frequency of occurrence is represented on the vertical axis.

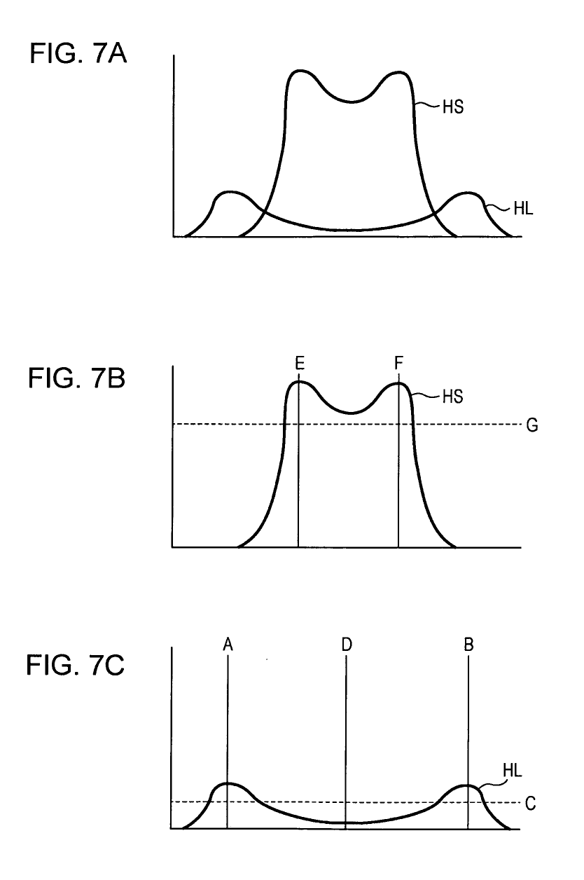

The histograms generated for different code lengths exhibit distributions shown in FIG. 7A. FIG. 7A shows a voltage distribution histogram HS for the smallest-code-length waveform and a voltage distribution histogram HL for the largest-code-length waveform. The histogram HS for the smallest-code-length waveform has its peaks at upper positions in a central portion. The histogram HL for the largest-code-length waveform has its peaks near the ends on both sides.

The histogram generator 26 stores the voltage distribution histogram HS for the smallest code length 2T into the 2T histogram storage 31, and the voltage distribution histogram HL for the largest code length 8T into the 8T histogram storage 33.

The mean value determiner 32 obtains the sum of the top and bottom levels IST and ISB of the waveform corresponding to the smallest code length of the recorded signal from the voltage distribution histogram HS stored in the 2T histogram storage 31, the sum being used in calculating the test-exposure asymmetry value.

Specifically, the mean value determiner 32 first assumes that portions around the two peaks of the voltage distribution histogram HS shown in FIG. 7B are approximate to the normal distribution. Subsequently, the mean value determiner 32 calculates the weighted mean of a portion of the distribution data ranging from the peaks to a level slightly lower than the peaks, i.e., to the level shown by line G in FIG. 7B corresponding to, for example, two thirds of the peak value. On the basis of the weighted mean calculated in this manner, the mean value determiner 32 determines the sum of the top and bottom levels IST and ISB, i.e., the mean value, of the signal waveform corresponding to the smallest code length.

The mean value determiner 32 may employ any other calculation method, as long as the method is to calculate the values at points F and E shown in FIG. 7B representing the top and bottom levels IST and ISB, respectively, in the form of two peaks of the voltage distribution histogram HS. For example, the mean value determiner 32 may determine the representative points by using the modal or median values of the distribution data around the two peaks of the voltage distribution histogram HS, or by approximating the distribution data with an nth-order curve and taking the maximal values of the approximated curve.

The top value determiner 34 and the bottom value determiner 35 obtain the top and bottom levels ILT and ILB, respectively, of the waveform corresponding to the largest code length of the recorded signal from the voltage distribution histogram HL stored in the 8T histogram storage 33.

Specifically, referring to FIG. 7C, the top value determiner 34 divides the voltage distribution histogram HL into right and left segments with respect to slice level value D, assumes that portions around the two peaks of the voltage distribution histogram HL are approximate to the normal distribution, and calculates the weighted mean of a portion of the distribution data ranging from peak B to a level slightly lower than peak B, i.e., to the level shown by line C in FIG. 7C corresponding to, for example, two thirds of the peak value. On the basis of the weighted mean calculated in this manner, the top value determiner 34 obtains the top level ILT.

Referring again to FIG. 7C, the bottom value determiner 35 divides the voltage distribution histogram HL into right and left segments with respect to slice level value D, assumes that portions around the two peaks of the voltage distribution histogram HL are approximate to the normal distribution, and calculates the weighted mean of a portion of the distribution data ranging from peak A to a level slightly lower than peak A, i.e., to the level shown by line C in FIG. 7C corresponding to, for example, two thirds of the peak value. On the basis of the weighted mean calculated in this manner, the bottom value determiner 35 obtains the bottom level ILB.

The top value determiner 34 and the bottom value determiner 35 may employ any other calculation method, as long as the method is to calculate the values at points B and A shown in FIG. 7C representing the top and bottom levels ILT and ILB, respectively, in the form of two peaks of the voltage distribution histogram HL. For example, the top value determiner 34 and the bottom value determiner 35 may obtain the representative points by using the modal or median values of the distribution data around the two peaks of the voltage distribution histogram HL, or by approximating the distribution data with an nth-order curve and taking the maximal values of the approximated curve.

The arithmetic part 36 calculates the test-exposure asymmetry value from the sum of the top and bottom levels IST and ISB determined by the mean value determiner 32, the top level ILT determined by the top value determiner 34, and the bottom level ILB determined by the bottom value determiner 35.

Thus, the asymmetry calculating unit 16 configured as above obtains the representative points from the peaks of the voltage distribution histograms even if the S/N ratio of the detector signal is not good. Therefore, the asymmetry calculating unit 16 accurately calculates the asymmetry value representing the signal characteristic of the beam reflected from a portion of the resist layer 101 that has undergone test exposure.

The offset setting unit 17 sets the focus offset value in the exposure process by utilizing a characteristic that the test-exposure asymmetry value changes unidirectionally as the formation of a portion of the pit-and-land pattern corresponding to the smallest code length becomes poorer with the deviation of the focal length from the optimum value.

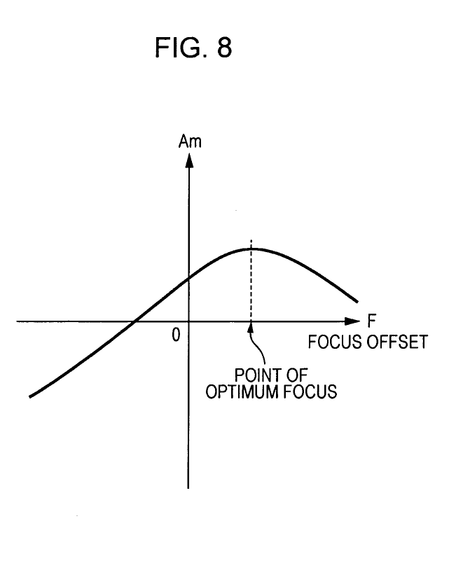

FIG. 8 shows a graph in which the horizontal axis represents the focus offset value that is set in test exposure and the vertical axis represents the test-exposure asymmetry value. In the case where the resist layer 101 containing the defective transition-metal oxide is employed, the test-exposure asymmetry value changes in such a manner as to be convex upward as shown in FIG. 8.

The test-exposure asymmetry value changes in this manner because of the following reason. The resist layer 101 containing the defective transition-metal oxide expands in the thickness direction because of thermal deformation occurring with the application of a laser beam to which the resist layer 101 responds. When a laser beam having such a power that the resist layer 101 shows no response is applied to the expanded portion of the resist layer 101, the feedback beam from the expanded portion of the resist layer 101 is detected as a relatively small value by the detector 14.

Therefore, as the focal length deviates from the optimum value and the formation of the portion of the pit-and-land pattern corresponding to the smallest code length becomes poorer, the values of IST and ISB become larger relative to the values of ILT and ILB, respectively. Consequently, the test-exposure asymmetry value is reduced monotonously. In other words, when the test-exposure asymmetry value is the largest, the optimum focal length is realized. That is, the portions of the pit-and-land patterns corresponding to all of the code lengths, from the smallest code length to the largest code length, respond to the laser beam.

Utilizing such a characteristic, the offset setting unit 17 stores the focal length corresponding to the maximum one of the test-exposure asymmetry values calculated by the asymmetry calculating unit 16 for individual changes in the focus offset value into an internal memory 17a thereof before the exposure process is performed. With reference to the information stored in the internal memory 17a, the offset setting unit 17 sets the focus offset value for the laser beam to be employed in the exposure process.

In the exposure process performed by the exposure apparatus 1, the focus servo control unit 15 controls, with reference to the focus offset value that is set by the offset setting unit 17, the focal length of the lens system 13 such that the resist layer 101 is exposed to the laser beam.

Thus, in the exposure apparatus 1, the focus offset value is set by utilizing the characteristic that the test-exposure asymmetry value changes unidirectionally as the formation of a first portion of the pit-and-land pattern that is of the smallest size becomes poorer with the deviation of the focus offset from the optimum value. Hence, the exposure apparatus 1 can operate such that the focal length of the lens system 13 is adjusted to the optimum value while reduction in the efficiency of the overall microfabrication process is suppressed.

Such suppression of reduction in the efficiency of the overall microfabrication process is employed because of the following reason. In such a method, whether the focus offset is optimum or not can be usually determined by examining the chemical changes occurring in the exposed areas after test exposure, even without examining the shape of the pit-and-land pattern obtained after the development process or the shape of the pit-and-land pattern transferred to the stamper.

In the exposure apparatus 1, exposure is performed on the resist layer 101 in which the exposed areas expand in the thickness direction, relative to the other areas, because of thermal deformation. The embodiment is also applicable to a resist layer in which the properties in the exposed areas change in such a manner as to contract, for example. In such a case also, the test-exposure asymmetry value calculated for every change in the focus offset value changes monotonously and unidirectionally with respect to an arbitrary point. Therefore, the focus offset value for the laser beam with which the exposure apparatus performs exposure is set to a value corresponding to the maximal test-exposure asymmetry value.

The exposure apparatus according to the embodiment of the present invention is also applicable to processes other than the process of manufacturing a master optical disc described above.

For example, the exposure apparatus according to the embodiment of the present invention is applicable to a process in which exposure is performed in any pattern, other than a signal pattern, including pits and lands arranged in a specific scanning direction by selectively applying a laser beam to a resist layer, provided on a substrate, to be subjected to microfabrication in which the exposed areas are developed. In such a microfabrication process, the test-exposure asymmetry value is evaluated as the displacement between the center axis of a signal waveform representing a beam reflected from a first portion of the pit-and-land pattern having the smallest width and the center axis of a signal waveform representing a beam reflected from a second portion of the pit-and-land pattern having a width larger than that of the first portion.

That is, the focal length is adjusted by utilizing a characteristic that the displacement between the center axes of the signal waveforms representing the beams reflected from the first and second portions of the pit-and-land pattern changes unidirectionally as the focal length deviates from the optimum value. Specifically, in the exposure apparatus, a point where the aforementioned displacement between the center axes that changes with the focal length is maximal is defined as the point of reference focal length. Thus, the focal length of the lens system that focuses the laser beam on the resist layer is adjusted to the optimum value in the exposure process.

The exposure apparatus according to the embodiment of the present invention is also applicable to any cases other than the case where exposure is performed on a resist layer in which the exposed areas undergo thermal deformation. For example, the exposure apparatus is applicable to a case where exposure is performed on a resist layer formed on a substrate and whose physical properties, such as the refractive index, change when exposed. In this case, the changes in the physical properties are detected with a laser beam having such a power that the resist layer shows no response, and a point where the aforementioned displacement between the center axes that changes with the focal length is maximal is defined as the point of reference focal length.

The present application contains subject matter related to that disclosed in Japanese Priority Patent Application JP 2010-037496 filed in the Japan Patent Office on Feb. 23, 2010, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. An exposure apparatus comprising:
an exposure unit selectively performing exposure on a resist layer provided on a substrate with a first laser beam focused on the resist layer by a lens system, the resist layer being subjected to microfabrication in which exposed areas thereof exposed to the first laser beam are developed, the exposure being performed in a pattern including pits and lands arranged in a scanning direction;
a detecting unit detecting a reflection of a second laser beam applied through the lens system to the resist layer selectively exposed to the first laser beam, the second laser beam being produced by changing a focal length of the lens system such that the resist layer is prevented from responding to the second laser beam;
a calculating unit calculating, from a result of the detection by the detecting unit, a displacement between a center axis of a signal waveform representing a beam reflected from a first portion of the pattern having a smallest width and a center axis of a signal waveform representing a beam reflected from a second portion of the pattern having a width larger than that of the first portion;
a setting unit setting the focal length of the lens system to such a value that the displacement between the center axes of the signal waveforms that is calculated by the calculating unit for every change in the focal length is maximal; and
a control unit controlling the exposure unit to expose the resist layer to the first laser beam focused thereon by the lens system with the focal length that is set by the setting unit.

2. The exposure apparatus according to claim 1, wherein the exposed areas of the resist layer are thermally deformed relative to other areas.

3. The exposure apparatus according to claim 1, wherein the resist layer contains a defective transition-metal oxide.

4. The exposure apparatus according to claim 1,
wherein the substrate and the resist layer in combination form a master optical disc from which the pattern is transferred to an optical-disc-manufacturing stamper, the pattern representing a signal to be recorded on an optical disc; and
wherein the calculating unit calculates an asymmetry value representing the displacement between the center axis of the signal waveform representing the beam reflected from the first portion of the pattern where the signal has a smallest code length and the center axis of the signal waveform representing the beam reflected from the second portion of the pattern where the signal has a largest code length.

5. The exposure apparatus according to claim 4,
wherein the exposed areas of the resist layer expand in a thickness direction because of thermal deformation;
wherein the calculating unit calculates the asymmetry value in accordance with the following expression:
{(ILT+ILB)−(IST+ISB)}/{2×(ILT−ILB)}
where IST and ISB denote top and bottom levels, respectively, of the signal waveform representing the beam reflected from the first portion of the pattern where the signal has the smallest code length, and ILT and ILB denote top and bottom levels, respectively, of the signal waveform representing the beam reflected from the second portion of the pattern where the signal has the largest code length; and
wherein the setting unit sets the focal length of the first laser beam to such a value that the asymmetry value calculated by the calculating unit for every change in the focal length is maximal.

6. An exposure method comprising the steps of:
detecting a reflection of a second laser beam applied to a resist layer provided on a substrate, the second laser beam being set such that the resist layer is prevented from responding thereto, the resist layer being subjected to microfabrication in which exposure is selectively performed thereon with a first laser beam focused by a lens system of an exposure apparatus and exposed areas thereof are developed, the exposure being performed in a pattern including pits and lands arranged in a scanning direction;
calculating, from a result of the detection, a displacement between a center axis of a signal waveform representing a beam reflected from a first portion of the pattern having a smallest width and a center axis of a signal waveform representing a beam reflected from a second portion of the pattern having a width larger than that of the first portion; and
controlling the exposure apparatus to perform exposure on the resist layer by setting a focal length of the lens system to such a value that the displacement between the center axes of the signal waveforms that is calculated for every change in the focal length is maximal.
